(19) United States
(12) Patent Application Publication
(10) Pub. No.: US 2016/0056036 A1
(43) Pub. Date: Feb. 25, 2016

(54) TEMPLATE, TEMPLATE FORMING METHOD, AND SEMICONDUCTOR DEVICE MANUFACTURING METHOD

(71) Applicant: KABUSHIKI KAISHA TOSHIBA, Tokyo (JP)

(72) Inventors: Hiroshi TOKUE, Yokohama (JP); Masayuki HATANO, Yokohama (JP); Yohko KOMATSU, Kawasaki (JP); Hiroyuki KASHIWAGI, Fujisawa (JP); Masatoshi TSUJI, Kawasaki (JP)

(21) Appl. No.: 14/633,263

(22) Filed: Feb. 27, 2015

(30) Foreign Application Priority Data
Aug. 21, 2014 (JP) 2014-168551

(51) Int. Cl. H01L 21/027; B24C 1/04; B29C 33/38; H01L 21/3105; B29C 59/02

(52) U.S. Cl. CPC H01L 21/0271; H01L 21/31058; B29C 59/026; B29C 33/3842; B24C 1/04; B29K 2101/00

(57) ABSTRACT

According to one embodiment, a template is provided which comprises a template pattern having protrusion pattern feature and recess pattern feature. High contact-angle portion whose contact angle is higher than side surface of the template pattern is placed in the template. The high contact-angle portion is placed in at least either top surface of the protrusion pattern feature or bottom surface of the recess pattern feature from among surfaces of the template pattern.

### CROSS-REFERENCE TO RELATED APPLICATIONS

This application is based upon and claims the benefit of priority from Japanese Patent Application No. 2014-168551, filed on Aug. 21, 2014; the entire contents of which are incorporated herein by reference.

### FIELD

Embodiments described herein relate generally to a template, a template forming method, and a semiconductor device manufacturing method.

### BACKGROUND

In these years, an imprint method is attracting attention as one of the processes used in forming semiconductor devices. In this imprint method, a template that is a master mold is used. A template pattern to be transferred onto substrates such as wafers is formed in this template. In the imprint process, the template is made to touch a photo-curing organic material (resist) coated on the substrate. Further, with the template touching the resist, light is irradiated onto the resist. Thus, the resist is cured, and the template is mold-removed from the cured resist, so that a resist pattern is formed on the substrate.

However, in the imprint method, when the template is mold-removed from the resist, stress is applied between the template pattern and the resist. Hence, the resist pattern may be damaged, resulting in pattern defects. With this imprint method, it is desired to increase fill-ability while reducing mold-removing force in removing the template from the resist.

### BRIEF DESCRIPTION OF THE DRAWINGS

FIG. 1 is a diagram showing the configuration of an imprint apparatus comprising a template according to an embodiment;

FIGS. 2A to 2D are diagrams for explaining the procedure of an imprint process according to the embodiment;

FIG. 3 is a diagram showing the configuration of the template according to the embodiment;

FIGS. 4A, 4B are diagrams showing the configuration in cross section of a high contact-angle portion according to the embodiment;

FIGS. 5A, 5B are diagrams for explaining a characteristic of the high contact-angle portion according to the embodiment;

FIGS. 6A, 6B are perspective views of the high contact-angle portions according to the embodiment;

FIG. 7 is a perspective view of a high contact-angle portion whose space regions are hole-shaped pattern features according to the embodiment;

FIG. 8 is a perspective view of a high contact-angle portion having a rough surface according to the embodiment; and

FIG. 9 is a graph showing the relation between the upper-surface-area proportion and the contact angle.

### DETAILED DESCRIPTION

According to one embodiment, a template is provided which comprises a template pattern having protrusion pattern feature and recess pattern feature. High contact-angle portion whose contact angle is higher than side surface of the template pattern is placed in the template. The high contact-angle portion is placed in at least either top surface of the protrusion pattern feature or bottom surface of the recess pattern feature from among surfaces of the template pattern.

The template, template forming method, and semiconductor device manufacturing method according to an embodiment will be described in detail below with reference to the accompanying drawings. The present invention is not limited to this embodiment.

### Embodiment

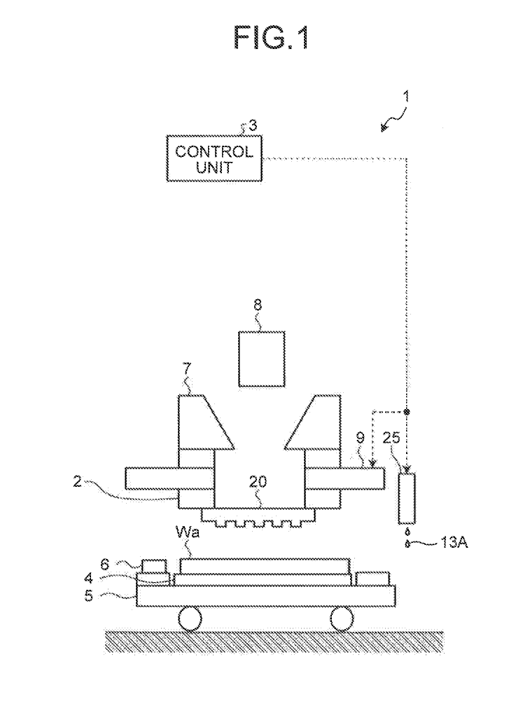

FIG. 1 is a diagram showing the configuration of an imprint apparatus. The imprint apparatus 1 is an apparatus which transfers the template pattern of a template 20, a mold substrate, onto a substrate subject to transfer such as a wafer Wa. The imprint apparatus 1 forms a pattern on the wafer Wa using an imprint method such as nano-imprint photolithography. The template 20 is a master mold, and the template pattern is a circuit pattern or the like to be transferred onto the wafer Wa. The template 20 is formed of a quartz glass substrate or the like.

In the template 20 of the present embodiment, faces whose contact angles are higher than a predetermined value are formed on the upper surfaces and the like except for the sidewall surfaces of the template pattern that is a recess/protrusion (concave/convex) pattern. Hereinafter a portion whose contact angle is higher than the predetermined value is called a high contact-angle portion. The high contact-angle portion is higher in contact angle than, e.g., the quartz glass substrate forming the template 20.

The imprint apparatus 1 comprises a master stage 2, a control unit 3, a substrate chuck 4, a sample stage 5, a reference mark 6, an alignment sensor 7, a UV light source 8, a stage base 9, and a liquid dropping device 25.

The sample stage 5 has the wafer Wa mounted thereon and moves in a plane (horizontal plane) parallel to the wafer Wa mounted. The sample stage 5 moves the wafer Wa underneath the liquid dropping device 25 when being to drop a resist 13A as transfer material onto the wafer Wa. Further, the sample stage 5 moves the wafer Wa underneath the template 20 when being to perform an imprint process on the wafer Wa.

The substrate chuck 4 is provided on the sample stage 5. The substrate chuck 4 fixes the wafer Wa at a predetermined position on the sample stage 5. Further, the reference mark 6 is provided on the sample stage 5. The reference mark 6 is a mark for detecting the position of the sample stage 5 and is used for alignment when loading the wafer Wa onto the sample stage 5.

The master stage 2 is provided on the wafer Wa side, that is, the bottom side of the stage base 9. The master stage 2 has the template 20 fixed thereto at a predetermined position by vacuum suction or the like from the back side (opposite side to the template pattern) of the template 20.

The stage base 9 supports the template 20 via the master stage 2 and presses the template pattern of the template 20 into the resist 13A on the wafer Wa. The stage base 9 moves in vertical directions, thereby pressing the template 20 into the resist 13A and separating (mold-removing) the template 20 from the resist 13A. Further, the alignment sensor 7 is provided on the stage base 9. The alignment sensor 7 is a sensor for performing the position detection of the wafer Wa and the position detection of the template 20.

The liquid dropping device 25 is a device that drops the resist 13A onto the wafer Wa by an ink jet method. An ink jet head (not shown) provided in the liquid dropping device 25 has multiple fine holes through which to eject droplets of the resist 13A.

The UV light source 8 is a light source emitting UV light and is provided above the stage base 9. The UV light source 8 irradiates UV light from above the template 20 with the template 20 being pressed into the resist 13A.

The control unit 3 is connected to the constituents of the imprint apparatus 1 to control the constituents. FIG. 1 shows that the control unit 3 is connected to the liquid dropping device 25 and the stage base 9 while connection to the other constituents is omitted from the illustration.

When being to imprint onto the wafer Wa, the wafer Wa mounted on the sample stage 5 is moved under the liquid dropping device 25. Then, a resist 13A is dropped onto a predetermined shot position on the wafer Wa.

After the resist 13A is dropped onto the wafer Wa, the wafer Wa on the sample stage 5 is moved under the template 20. Then, the template 20 is pressed into the resist 13A on the wafer Wa.

After the template 20 and the resist 13A are made to touch for a predetermined time, the UV light source 8 irradiates (V light onto the resist 13A in this state so as to be cured, so that a transferred pattern corresponding to the template pattern is formed in the resist 13A on the wafer Wa. Subsequently, the imprint process for the next shot is performed.

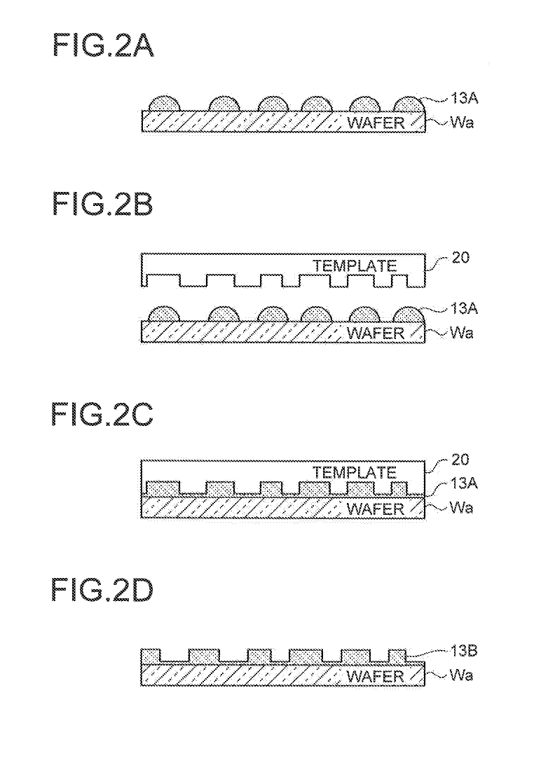

Next, the procedure of the imprint process will be described. FIGS. 2A to 2D are diagrams for explaining the procedure of the imprint process. FIGS. 2A to 2D show cross-sectional views of the wafer Wa, the template 20, etc., in the imprint process.

As shown in FIG. 2A, droplets of the resist 13A are dropped onto the upper surface of the wafer Wa. Thus, the droplets of the resist 13A dropped onto the wafer Wa spread on the wafer Wa. Then the template 20 is moved over the resist 13A as shown in FIG. 2B, and the template 20 is pressed against the resist 13A as shown in FIG. 2C. As such, when the template 20, made by cutting a pattern in a quartz substrate or the like, is made to touch the resist 13A, the resist 13A flows into the template pattern of the template 20 by a capillary phenomenon.

After letting the resist 13A fill the template 20 over a preset time, UV light is irradiated. Thus, the resist 13A is cured. Then, a resist pattern 13B, the inverse of the template pattern, is formed on the wafer Wa by mold-removing the template 20 from the cured resist pattern 13B as shown in FIG. 2D.

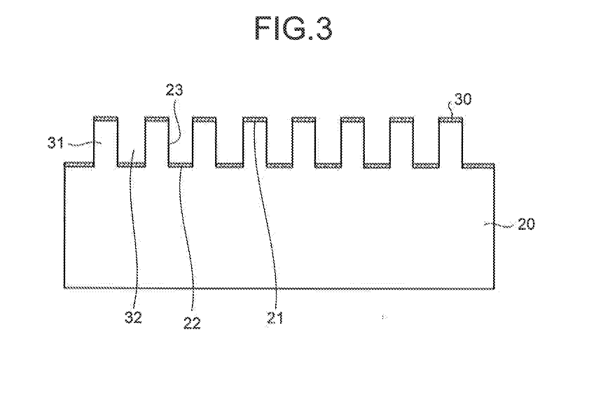

FIG. 3 is a diagram showing the configuration of the template according to the embodiment. FIG. 3 shows the configuration in cross section of the template 20. In the template 20, the template pattern that is a recess/protrusion pattern is formed. In other words, the template pattern of the template 20 has multiple protrusion pattern features 31 and multiple recess pattern features 32.

The template pattern has top surfaces 21 that are upper surfaces of the protrusion pattern features 31, bottom surfaces 22 sandwiched between the protrusion pattern features 31, and sidewall surfaces 23 of the protrusion pattern features 31. In other words, the template pattern has the bottom surfaces 22 of the recess pattern features 32, the top surfaces 21 sandwiched between the recess pattern features 32, and the sidewall surfaces 23 of the recess pattern features 32.

In the present embodiment, high contact-angle portions 30 are formed on the top surfaces 21 and bottom surfaces 22 from among the top surfaces 21, bottom surfaces 22, and sidewall surfaces 23 that the template 20 has. The high contact-angle portion 30 is an area higher in contact angle than the surface of the template 20. Thus, the high contact-angle portions 30 of the top surfaces 21 and bottom surfaces 22 are higher in contact angle than the sidewall surfaces 23. Note that the high contact-angle portion 30 need only be formed on at least either of the top surfaces 21 and bottom surfaces 22 that the template 20 has.

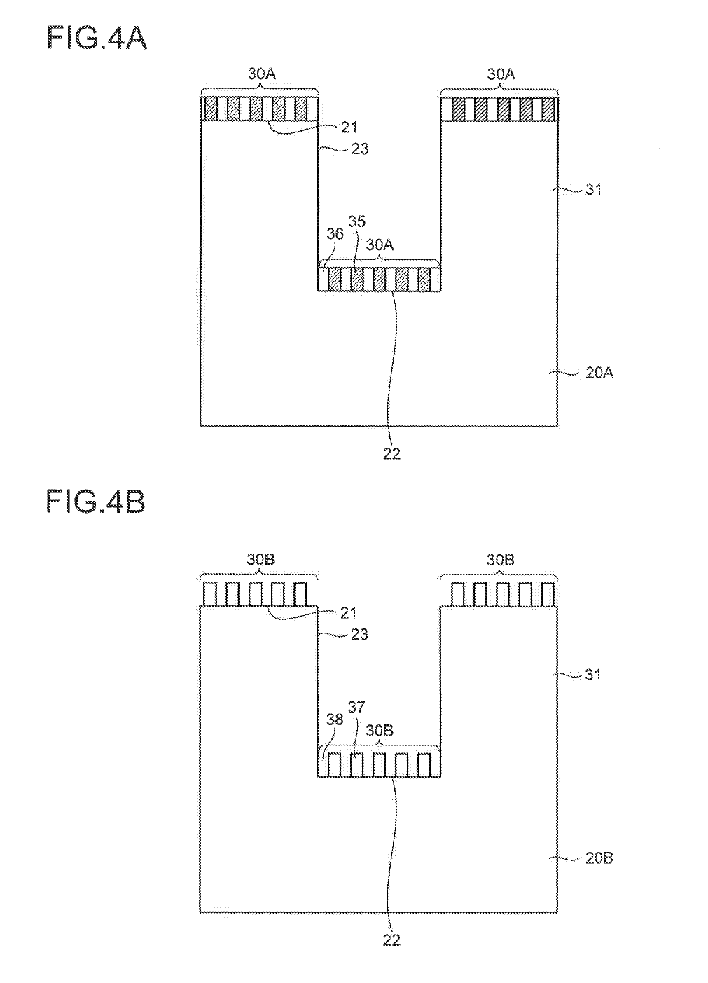

FIGS. 4A, 4B are diagrams showing the configuration in cross section of the high contact-angle portion. FIG. 4A shows the configuration in cross section of a template 20A that is a first example of the template 20. FIG. 4B shows the configuration in cross section of a template 20B that is a second example of the template 20.

As shown in FIG. 4A, the template 20A has high contact-angle portions 30A formed on the top surface 21 and bottom surface 22, the high contact-angle portion 30A being an example of the high contact-angle portion 30. The high contact-angle portion 30A is formed of first members 35 and second members 36. Specifically, the high contact-angle portion 30A has the first members 35 and second members 36 arranged such that the first members 35 and second members 36 are exposed at its surface.

As shown in FIG. 4B, the template 20B has high contact-angle portions 30B formed on the top surface 21 and bottom surface 22, the high contact-angle portion 30B being an example of the high contact-angle portion 30. The high contact-angle portion 30B is formed of third members 37 and space regions 38. Specifically, the high contact-angle portion 30B has the third members 37 and space regions 38 arranged such that the third members 37 and space regions 38 are exposed at its surface.

The third member 37 is, for example, of the same material as the template 20B. The third member 37 is, for example, of quartz glass. The space region 38 is a region having no member placed (but air). The template 20B is formed, for example, by cutting the space regions 38 in the top surface 21 and bottom surface 22. Note that the third member 37 may be of material different from that of the template 20B.

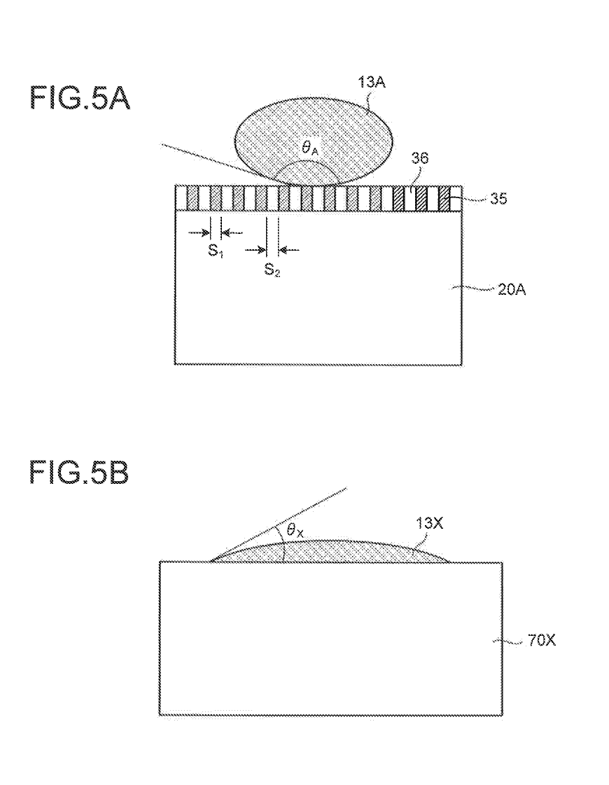

Next, the configuration and characteristic of the high contact-angle portion will be described. Here, the configuration and characteristic of the high contact-angle portion 30A will be described. FIGS. 5A, 5B are diagrams for explaining a characteristic of the high contact-angle portion. FIG. 5A shows the configuration in cross section of the high contact-angle portion 30A and the resist 13A. FIG. 5B shows the configuration in cross section of a template 70X having no high contact-angle portion and a resist 13X.

As shown in FIG. 5A, let S₁ be the proportion of the upper surface area of the first members 35 and S₂ be the proportion of the upper surface area of the second members 36. Further, let Θ_{S1} be the contact angle of the first members 35 and Θ_{S2} be the contact angle of the second members 36.

Herein, the upper surface area is the area of the upper surface when the template 20A is seen from the upper surface side thereof. The proportion S₁ is the upper surface area of the first members 35 divided by the total area of the upper surface area of the first members 35 and that of the second members 36. In other words, the proportion S₁ is the area occupancy share of the first members 35 in the high contact-angle portion 30A.

Likewise, the proportion S₂ is the upper surface area of the second members 36 divided by the total area of the upper surface area of the first members 35 and that of the second members 36. In other words, the proportion S₂ is the area occupancy share of the second members 36 in the high contact-angle portion 30A.

Herein, the contact angle is an angle made by the resist 13A and the solid surface (first member 35 or second member 36) of the template pattern. Thus, the contact angle denotes the wettability of the resist 13A to the template pattern.

In general, if the solid surface is formed of two types of members, the equation of Cassie holds. For example, where S₁, S₂, Θ_{S1}, Θ_{S2} denote the upper-surface-area proportions and contact angles of the composite surface formed by the first members 35 and the second members 36 respectively as mentioned above, the following equation (1) holds. In the equation (1), Θ_{A} is the apparent contact angle of the composite surface formed by the first members 35 and the second members 36.

cos Θ_{A}=S₁×cos Θ_{S1}+S₂×cos Θ_{S2} (1)

For example, the composite surface having the first members 35 of a contact angle of 130° and the second members 36 of a contact angle of 170° is formed on the template 20A. In this case, it is supposed that the surface-area proportion of the first members 35 is 0.6 and that the surface-area proportion of the second members 36 is 0.4. Letting Θ₂ be the apparent contact angle of the composite surface formed by the first members 35 and the second members 36, Θ₂ is given by the following equation (2) based on the above equation (1).

cos Θ₂=(0.6×cos 170°)+(0.4×cos 130°)=−0.847 (2)

Thus, the calculated value of Θ₂ is 148°. Because the measured value of Θ₂ was 150°, the calculated value and measured value of Θ₂ almost coincide. As such, in the present embodiment, the composite surface formed by two types of members is provided on the surface of the template 20A, and hence the contact angle of the template 20A could be increased.

Next, the configuration and characteristic of the high contact-angle portion 30B will be described. It is supposed that the upper-surface-area proportion of the third members 37 is 0.6 in the high contact-angle portion 30B and that the upper-surface-area proportion of the space regions 38 is 0.4. And it is supposed that the contact angle of the third members 37 is 20° and that the contact angle of the space regions 38 is 180°. Letting Θ₃ be the apparent contact angle of the composite surface formed by the third members 37 and the space regions 38, Θ₃ is given by the following equation (3) based on the aforementioned equation (1).

cos Θ₃=(0.6×cos 20°)+(0.4×cos 180°)=−0.0603 (3)

Thus, the calculated value of Θ₃ is 93°. It is found out from our experiment results that the contact angle needs to be 60° or greater in order to make mold-removing force small enough to avoid the occurrence of a defect at mold-removal. Accordingly, in the present embodiment, the template 20 is formed such that the contact angle of the high contact-angle portion 30 to the resist 13A is 60° or greater.

The templates 20A, 20B shown in FIGS. 4A and 4B satisfy the condition that the contact angle is 60° or greater. With either of the templates 20A and 20B, we could perform imprinting such that mold-removal defects such as deformation, falling-down, and tearing-off of the resist pattern were suppressed.

In contrast, when the resist 13X, an organic material, was dropped onto the template 70X having no high contact-angle portion 30 as shown in FIG. 5B, the contact angle Θ_{X} between the resist 13X and the template 70X was 20°. As such, with the template 70X having no high contact-angle portion 30, the contact angle remains small.

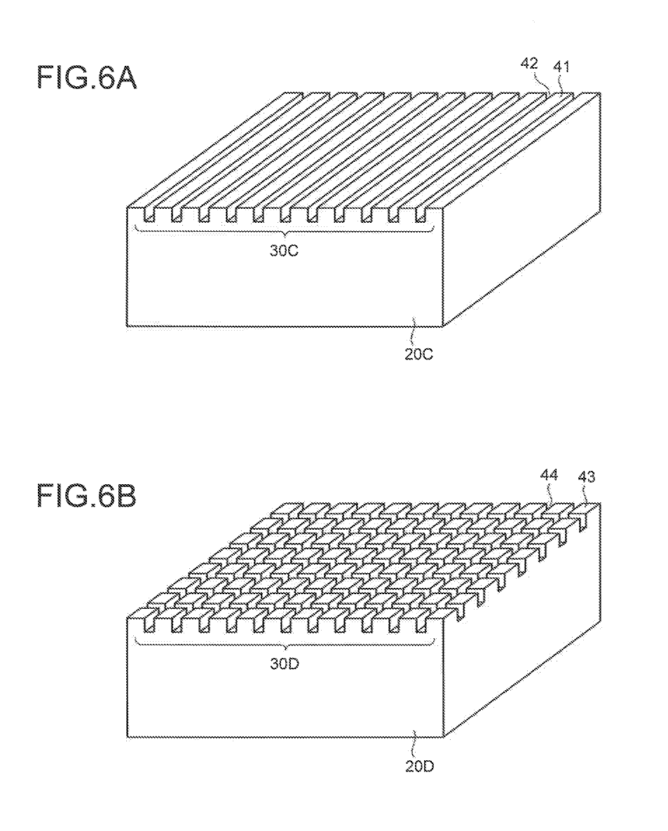

FIGS. 6A, 6B are perspective views of the high contact-angle portions. FIG. 6A shows the configuration of a template 20C that is a third example of the template 20. The template 20C has a high contact-angle portion 30C that is an example of the high contact-angle portion 30.

The high contact-angle portion 30C has a top surface 21 in a rectangular-pillar pattern that is like a line pattern. When the high contact-angle portion 30C is seen from the upper surface side, in the high contact-angle portion 30C, the third members 37 form a line pattern 41, and the space regions 38 form a line pattern 42. In other words, in the high contact-angle portion 30C shown in FIG. 6A, the third members 37 and the space regions 38 form a line & space pattern.

FIG. 6B shows the configuration of a template 20D that is a fourth example of the template 20. The template 20D has a high contact-angle portion 30D that is an example of the high contact-angle portion 30.

The high contact-angle portion 30D has a top surface 21 in a rectangular-pillar pattern of rectangles (e.g., squares). Specifically, in the high contact-angle portion 30D, the third members 37 form a rectangular-pillar-like protrusion pattern 43, and the space regions 38 form a groove pattern 44 in which the grooves surround the features of the protrusion pattern 43.

As such, the upper surface shape of the protrusion pattern features when the composite surface is seen from above may be a line shape as in the high contact-angle portion 30C or a rectangular shape as in the high contact-angle portion 30D.

The protrusion pattern 43 of the high contact-angle portion 30D may be a pattern of columns or a pattern of elliptic columns. Or the protrusion pattern 43 of the high contact-angle portion 30D may be a pattern of prisms having an upper surface shaped like a polygon other than a square. The space regions 38 may be hole-shaped pattern features. Or high contact-angle portions 30 may be formed by making the top surface 21 and the bottom surface 22 anisotropic rough surfaces.

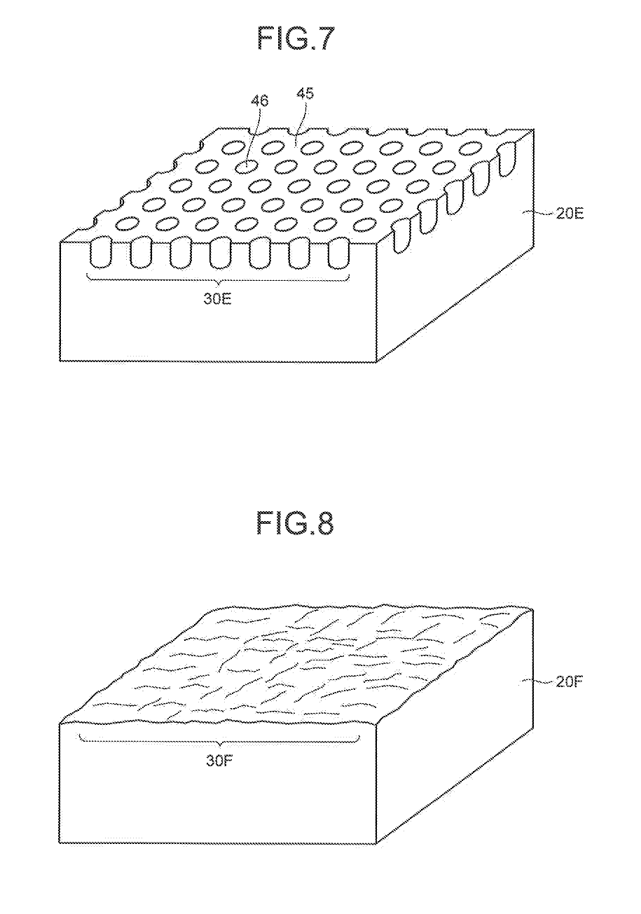

FIG. 7 is a perspective view of a high contact-angle portion whose space regions are hole pattern features. FIG. 7 shows the configuration of a template 20E that is a fifth example of the template 20. The template 20E has a high contact-angle portion 30E that is an example of the high contact-angle portion 30. In the high contact-angle portion 30E, the space regions 38 are hole pattern features 46, and the third members 37 are a pattern 45 that surrounds the hole pattern features 46.

FIG. 8 is a perspective view of a high contact-angle portion having a rough surface. FIG. 8 shows the configuration of a template 20F that is a sixth example of the template 20. The template 20F has a high contact-angle portion 30F that is an example of the high contact-angle portion 30. The high contact-angle portion 30F has an anisotropic rough upper surface with convexities and concavities.

Next, a method of forming the template 20 will be described. Here, a method of forming the template 20F will be described. Before forming the template 20F, the template 70X having no high contact-angle portion 30, etc., are prepared. Then, grains of an abrasive on the order of several nm are blasted at the template 70X from the upper surface (template pattern face) side for, e.g., 15 minutes by a sandblast method or the like. By this means, anisotropic grinding is performed on the upper surface of the template 70X. When anisotropic grinding is performed, an upper surface and a bottom surface are more polished than a sidewall surface. As a result, the template 20F is made from the template 70X. The template 20 may be made using hydrofluoric acid.

For example, in the template 20B shown in FIG. 4B, the widths of the third member 37 and the space region 38 are both 30 nm. The depth of the third member 37 is 3 to 100 nm (e.g., 80 nm). As a result of imprinting using the template 20B, the resist 13A became high in contact angle at the contact with the high contact-angle portion 30, resulting in a reduction in mold-removing force. Therefore, mold-removing force when the high contact-angle portion 30E existed was about 40% smaller than when the high contact-angle portion 30B (the composite surface) did not exist. Likewise, with the templates 20 other than the template 20B, mold-removing force was smaller than with the template 70X having no high contact-angle portion 30.

Further, when the high contact-angle portion 30B existed, fill-ability was improved over when the high contact-angle portion 30B did not exist. This was because the contact angle to the high contact-angle portion 30 is high, so that the resist 13A is less likely to wet the template 20B. As such, when the resist 13A is less likely to wet the template 20B, the resist 13A moves faster, resulting in a shorter filling time. As a result, the filling time when the high contact-angle portion 30B existed was 20% shorter than when the high contact-angle portion 30B did not exist.

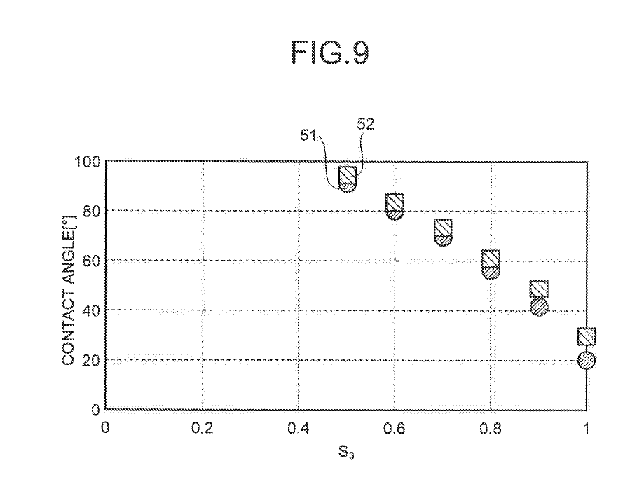

FIG. 9 is a graph showing the relation between the upper-surface-area proportion and the contact angle. Here, the relation between the upper-surface-area proportion (S₃) and the contact angle in the template 20B will be described. The horizontal axis of FIG. 9 represents the upper-surface-area proportion of the third members 37 in the high contact-angle portion 30B. The vertical axis of FIG. 9 represents the contact angle to the high contact-angle portion 30B.

As mentioned previously, the same relation as the equation (1) also holds for the template 20B. Let S₃ be the proportion of the upper surface area of the third members 37 and S₄ be the proportion of the upper surface area of the space regions 38. Further, let Θ_{S3} be the contact angle of the third members 37 and Θ_{S4} be the contact angle of the space regions 38. In this case, the following equation (4) holds. In the equation (4), Θ_{B} is the apparent contact angle of the composite surface formed by the third members 37 and the space regions 38.

cos Θ_{B}=S₃×cos Θ_{S3}+S₄×cos Θ_{S4} (4)

Because the space region 38 is filled with air or He (helium), Θ_{S4}=180° and thus cos Θ_{S4}=−1. Further, S₃+S₄=1. Therefore, the equation (4) is rewritten as the equation (5).

cos Θ_{B}=S₃×(1+cos Θ_{S3})−1 (5)

For example, if the contact angle Θ_{B} is 60° or greater, the mold-removing-ability of the template 20B will be good. And cos 60°=0.5. If the third member 37 is made of quartz glass, the contact angle (Θ_{S3}) of the third member 37 is, for example, 20°. Thus, if the third member 37 is made of quartz glass, it is desired to satisfy the inequality (6) so that good mold-removing-ability is obtained.

0.5>S₃×(1+cos 20°)−1 (6)

From the inequality (6), it is seen that, where the third member 37 is made of quartz glass, if S₃<0.773, good mold-removing-ability can be obtained. In FIG. 9, the characteristic 51 indicates the relation between S₃ and the contact angle (Θ_{B}) to the high contact-angle portion 30B when the contact angle (Θ_{S3}) of the third member 37 is 20°. Further, in FIG. 9, the characteristic 52 indicates the relation between S₃ and the contact angle (Θ_{B}) to the high contact-angle portion 30B when the contact angle (Θ_{S3}) of the third member 37 is 30°. From the inequality (Θ_{S3}), it is seen that, where the contact angle of the third member 37 is 30°, if S₃<0.804, good mold-removing-ability can be obtained.

The template 20 is made, for example, for each layer in the wafer process. A semiconductor device (semiconductor integrated circuit) is manufactured using the made templates 20. Specifically, imprinting is performed on the wafer Wa having the resist 13A coated thereon using the template 20. By this means, a resist pattern is formed on the wafer Wa. Then the under layer of the wafer Wa is etched with the resist pattern as a mask. Thus, an actual pattern corresponding to the resist pattern is formed on the wafer Wa. While a semiconductor device is manufactured, making the template 20 having the high contact-angle portion 30, imprinting, etching, etc., are repeated for each layer.

Note that three or more types of members may be arranged in the high contact-angle portion 30 or that space regions and two or more types of members may be arranged in the high contact-angle portion 30.

As described above, in the present embodiment, the template 20 comprises a template pattern having the protrusion pattern features 31 and the recess pattern features 32. And in the template 20, the high contact-angle portions 30, whose contact angle to the resist 13A is higher than a predetermined value, are formed in the surfaces other than the sidewall surfaces 23 from among the wall surfaces of the template pattern. Specifically, the high contact-angle portions 30 are formed in the top surfaces 21 and bottom surfaces 22 of the template pattern.

Thus, as to the template 20, with reducing its mold-removing force from the resist 13A, the fill-ability can be increased. Therefore, an imprint pattern with fewer pattern defects can be obtained by imprinting using any of the templates 20A to 20F.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising a template pattern having protrusion pattern feature and recess pattern feature, wherein high contact-angle portion whose contact angle is higher than side surface of the template pattern is placed in at least either top surface of the protrusion pattern feature or bottom surface of the recess pattern feature from among surfaces of the template pattern.

2. The template according to claim 1, wherein the high contact-angle portion is formed of a first pattern formed by first member and a second pattern formed by second member, and the first pattern and the second pattern are exposed at surface of the high contact-angle portion.

3. The template according to claim 1, wherein the high contact-angle portion is formed of a third pattern formed by third member and space region, and the third pattern is exposed at surface of the high contact-angle portion.

4. The template according to claim 3, wherein the high contact-angle portion is formed by cutting in the template pattern.

5. The template according to claim 1, wherein a contact angle of the high contact-angle portion to the resist is 60° or greater.

6. The template according to claim 3, wherein the third member is made of quartz glass, and proportion of the top surface of the third pattern in surface in which the high contact-angle portion is placed is smaller than 0.773.

7. The template according to claim 3, wherein the third pattern is a rectangular-pillar pattern that of top surface is a line pattern.

8. The template according to claim 3, wherein the third pattern is in a rectangular-pillar pattern that of top surface is a rectangle pattern.

9. The template according to claim 3, wherein the space region is a hole-shaped pattern feature.

10. The template according to claim 3, wherein the high contact-angle portion is formed of an anisotropic rough surface.

11. A template forming method comprising:
forming a template pattern having protrusion pattern feature and recess pattern feature; and
forming high contact-angle portion whose contact angle is higher than side surface of the template pattern in at least either top surface of the protrusion pattern feature or bottom surface of the recess pattern feature from among surfaces of the template pattern.

12. The template forming method according to claim 11, wherein the high contact-angle portion is formed such that a first pattern formed by first member and a second pattern formed by second member are exposed at surface of the high contact-angle portion.

13. The template forming method according to claim 11, wherein the high contact-angle portion is formed such that a third pattern formed by third member is exposed at surface of the high contact-angle portion with space region being between the third members of the third pattern.

14. The template forming method according to claim 13, wherein the high contact-angle portion is formed by cutting in the template pattern.

15. The template forming method according to claim 13, wherein the high contact-angle portion is formed using a sandblast method.

16. A semiconductor device manufacturing method comprising:
making a template having a template pattern formed therein; and
transferring a pattern corresponding to the template pattern onto a substrate by imprinting using the template,
wherein, when making the template, a template pattern having protrusion pattern feature and recess pattern feature is formed, and high contact-angle portion whose contact angle is higher than side surface of the template pattern is formed in at least either top surface of the protrusion pattern feature or bottom surface of the recess pattern feature from among surfaces of the template pattern.

17. The semiconductor device manufacturing method according to claim 16, wherein the high contact-angle portion is formed such that a first pattern formed by first member and a second pattern formed by second member are exposed at surface of the high contact-angle portion.

18. The semiconductor device manufacturing method according to claim 16, wherein the high contact-angle portion is formed such that a third pattern formed by third members is exposed at surface of the high contact-angle portion with space region being between the third members of the third pattern.

19. The semiconductor device manufacturing method according to claim 18, wherein the high contact-angle portion is formed by cutting in the template pattern.

20. The semiconductor device manufacturing method according to claim 18, wherein the high contact-angle portion is formed using a sandblast method.
